(19) United States
(12) Patent Application Publication
(10) Pub. No.: US 2015/0021674 A1
(43) Pub. Date: Jan. 22, 2015

(54) RADIATION IMAGE PICKUP UNIT AND RADIATION IMAGE PICKUP DISPLAY SYSTEM

(71) Applicant: Sony Corporation, Tokyo (JP)

(72) Inventors: Yasuhiro Yamada, Kanagawa (JP); Makoto Takatoku, Kanagawa (JP)

(73) Assignee: Sony Corporation, Tokyo (JP)

(21) Appl. No.: 14/320,777

(22) Filed: Jul. 1, 2014

(30) Foreign Application Priority Data
Jul. 16, 2013 (JP) 2013-147742

(51) Int. Cl. H01L 27/146

(52) U.S. Cl. CPC H01L 27/14643
USPC 257/292; 257/290

(57) ABSTRACT

A radiation image pickup unit includes: a plurality of pixels each configured to generate a signal charge based on a radiation; and a field effect transistor to readout the signal charges from the plurality of pixels. The transistor includes a semiconductor layer including an active layer, a first gate electrode disposed to face the semiconductor layer, a first gate insulating film provided between the semiconductor layer and the first gate electrode, and including a first silicon oxide film, a source electrode and a drain electrode that are electrically connected to the semiconductor layer, and a second silicon oxide film provided in a layer different from the first gate insulating film. The first silicon oxide film of the first gate insulating film is a porous film lower in film density than the second silicon oxide film.

### CROSS REFERENCE TO RELATED APPLICATIONS

This application claims the benefit of Japanese Priority Patent Application JP 2013-147742 filed Jul. 16, 2013, the entire contents of which are incorporated herein by reference.

### BACKGROUND

The present disclosure relates to a radiation image pickup unit acquiring an image based on radiations such as X-rays, and to a radiation image pickup display system provided with such a radiation image pickup unit.

There is proposed a radiation image pickup unit that acquires an image of an object as an electric signal, based on radiations such as X-rays (for example, Japanese Unexamined Patent Application Publication Nos. 2008-252074 and 2004-265935).

### SUMMARY

In the above-described radiation image pickup unit, a thin film transistor (TFT) is used as a switching element to read out signal charges from pixels. There is a disadvantage that reliability is deteriorated by characteristic degradation of the TFT.

It is desirable to provide a radiation image pickup unit capable of achieving high reliability while suppressing characteristic degradation of a transistor, and a radiation image pickup display system provided with such a radiation image pickup unit.

According to an embodiment of the disclosure, there is provided a radiation image pickup unit including: a plurality of pixels each configured to generate a signal charge based on a radiation; and a field effect transistor to readout the signal charges from the plurality of pixels. The transistor includes a semiconductor layer including an active layer, a first gate electrode disposed to face the semiconductor layer, a first gate insulating film provided between the semiconductor layer and the first gate electrode, and including a first silicon oxide film, a source electrode and a drain electrode that are electrically connected to the semiconductor layer, and a second silicon oxide film provided in a layer different from the first gate insulating film. The first silicon oxide film of the first gate insulating film is a porous film lower in film density than the second silicon oxide film.

According to an embodiment of the technology, there is provided a radiation image pickup display system provided with a radiation image pickup unit and a display unit configured to perform image display based on an image pickup signal that is obtained by the radiation image pickup unit. The radiation image pickup unit includes: a plurality of pixels each configured to generate a signal charge based on a radiation; and a field effect transistor to readout the signal charges from the plurality of pixels. The transistor includes a semiconductor layer including an active layer, a first gate electrode disposed to face the semiconductor layer, a first gate insulating film provided between the semiconductor layer and the first gate electrode, and including a first silicon oxide film, a source electrode and a drain electrode that are electrically connected to the semiconductor layer, and a second silicon oxide film provided in a layer different from the first gate insulating film. The first silicon oxide film of the first gate insulating film is a porous film lower in film density than the second silicon oxide film.

In the radiation image pickup unit and the radiation image pickup display system according to the respective embodiments of the present disclosure, in the transistor to read out the signal charges based on the radiation, from the pixels, the first gate insulating film provided between the semiconductor layer and the first gate electrode includes the first silicon oxide film. At this time, if the radiation enters the silicon oxide film, positive holes are generated which causes deterioration in characteristics of the semiconductor layer. However, when the first silicon oxide film is the predetermined porous film, such influence caused by the radiation to the semiconductor layer is reduced, and thus shift in threshold voltage is difficult to occur.

In the radiation image pickup unit and the radiation image pickup display system according to the respective embodiments of the disclosure, in the transistor to read out the signal charges based on the radiation, from the pixels, the first gate insulating film provided between the semiconductor layer and the first gate electrode includes the first silicon oxide film, and the first silicon oxide film is the porous film lower in film density than the second silicon oxide film provided in a layer different from the first gate insulating film. Accordingly, it is possible to suppress shift of the threshold voltage of the transistor caused by influence of the radiation. Consequently, it is possible to suppress characteristic deterioration of the transistor and to achieve high reliability.

It is to be understood that both the foregoing general description and the following detailed description are exemplary, and are intended to provide further explanation of the technology as claimed.

### BRIEF DESCRIPTION OF THE DRAWINGS

The accompanying drawings are included to provide a further understanding of the disclosure, and are incorporated in and constitute a part of this specification. The drawings illustrate embodiments and, together with the specification, serve to explain the principles of the technology.

FIG. 1 is a block diagram illustrating an entire configuration example of a radiation image pickup unit according to an embodiment of the disclosure.

FIG. 2A is a schematic diagram illustrating a schematic structure of a pixel section in a case of an indirect conversion type.

FIG. 2B is a schematic diagram illustrating a schematic structure of a pixel section in a case of a direct conversion type.

FIG. 3 is a circuit diagram illustrating a detailed configuration example of a pixel and the like illustrated in FIG. 1.

FIG. 4 is a sectional diagram illustrating a structure of a transistor illustrated in FIG. 3.

FIG. 5 is a block diagram illustrating a detailed configuration example of a column selection section illustrated in FIG. 1.

FIG. 6 is a characteristic diagram for explaining influence of radiation to transistor characteristics.

FIG. 7 is a characteristic diagram illustrating a shift amount of a threshold voltage in Examples and a comparative example.

FIG. 8 is a sectional diagram illustrating a structure of a transistor according to a modification 1.

FIG. 9 is a sectional diagram illustrating a structure of a transistor according to a modification 2.

FIG. 10 is a sectional diagram illustrating a structure of a transistor according to a modification 3.

FIG. 11 is a sectional diagram illustrating a structure of a transistor according to a modification 4.

FIG. 12 is a circuit diagram illustrating a configuration of a pixel and the like according to a modification 5.

FIG. 13 is a circuit diagram illustrating a configuration of a pixel and the like according to a modification 6.

FIG. 14 is a circuit diagram illustrating a configuration of a pixel and the like according to a modification 7-1.

FIG. 15 is a circuit diagram illustrating a configuration of a pixel and the like according to a modification 7-2.

FIG. 16 is a schematic diagram illustrating a schematic configuration of a radiation image pickup display system according to an application example.

### DETAILED DESCRIPTION

Hereinafter, a preferred embodiment of the present disclosure will be described in detail with reference to drawings. Note that description will be given in the following order.
1. Embodiment (an example of a radiation image pickup unit provided with a dual gate type transistor in which a silicon oxide film of a first gate insulating film is a porous film)
2. Modification 1 (an example of a transistor having a first gate insulating film of another stacked structure)
3. Modification 2 (an example of a transistor having a first gate insulating film of another stacked structure)
4. Modification 3 (an example of a top gate type transistor)
5. Modification 4 (an example of a bottom gate type transistor)
6. Modification 5 (an example of another passive pixel circuit)
7. Modification 6 (an example of another passive pixel circuit)
8. Modifications 7-1 and 7-2 (examples of active pixel circuit)
9. Application Example (an example of a radiation image pickup display system)

### Embodiment

### (Configuration)

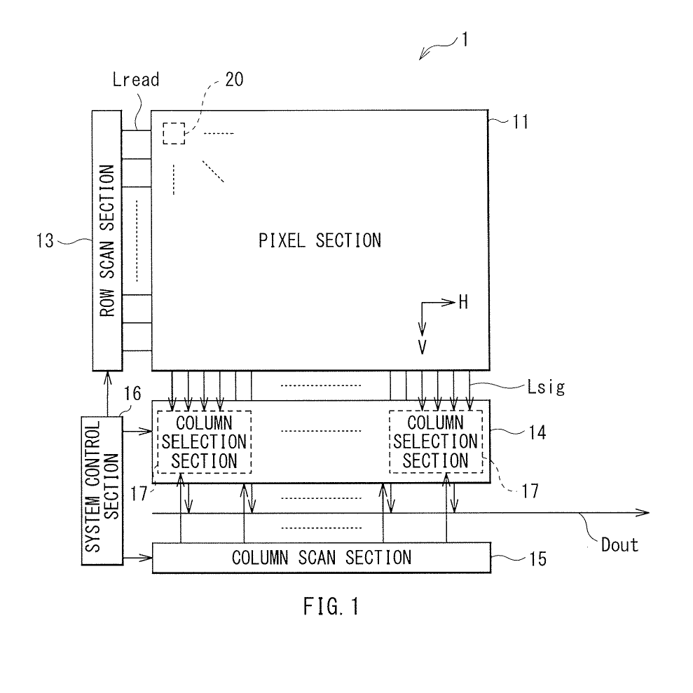

FIG. 1 illustrates a block configuration of an entire radiation image pickup unit (a radiation image pickup unit 1) according to an embodiment of the present disclosure. The radiation image pickup unit 1 reads information of an object (picks up an image of an object) based on incident radiations Rrad (such as α-rays, β-rays, γ-rays, and X-rays). The radiation image pickup unit 1 includes a pixel section 11, as well as includes a row scan section 13, an A/D conversion section 14, a column scan section 15, and a system control section 16 that serve as a drive circuit of the pixel section 11.

### (Pixel Section 11)

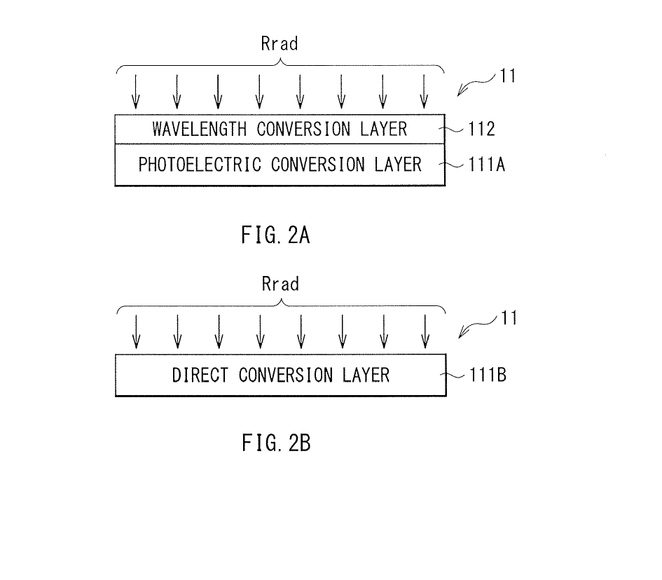

The pixel section 11 includes a plurality of pixels (image pickup pixels and unit pixels) 20 each generating a signal charge based on the radiation. The plurality of pixels 20 are two-dimensionally arranged in a matrix. Note that, as illustrated in FIG. 1, hereinafter, description will be given while a horizontal direction (a row direction) in the pixel section 11 is referred to as “H” direction, and a vertical direction (a column direction) is referred to as “V” direction. The radiation image pickup unit 1 may be a so-called indirect conversion type or a so-called direct conversion type as long as the radiation image pickup unit 1 uses a transistor 22 (described later) as a switching element for readout of the signal charges from the pixel section 11. FIG. 2A illustrates a structure of the pixel section 11 in the case of the indirect conversion type, and FIG. 2B illustrates a structure of the pixel section 11 in the case of the direct conversion type.

In the case of the indirect conversion type (FIG. 2A), the pixel section 11 includes a wavelength conversion layer 112 on a photoelectric conversion layer 111A (a light receiving surface side). The wavelength conversion layer 112 converts the wavelength of the radiation Rrad into a wavelength in a sensitive range of the photoelectric conversion layer 111 (for example, visible light). For example, the wavelength conversion layer 112 may be formed of a fluorescent substance (for example, CsI (Tl-added), Gd₂O₂S, BaFX (X is Cl, Br, I, or the like), scintillator such as NaI and CaF₂) that converts an X-ray into visible light. Such a wavelength conversion layer 112 is formed on the photoelectric conversion layer 111A with a planarizing film formed of, for example, an organic material or a spin on glass material in between. The photoelectric conversion layer 111A is configured to include a photoelectric conversion element (a photoelectric conversion element 21 described later) such as a photodiode.

In the case of the direct conversion type (FIG. 2B), the pixel section 11 includes a conversion layer (a direct conversion layer 111B) that absorbs incident radiations Rrad to generate an electric signal (positive holes and electrons). The direct conversion layer 111B may be formed of, for example, amorphous selenium (a-Se) semiconductor, cadmium tellurium (CdTe) semiconductor, or the like.

As described above, although the radiation image pickup unit 1 may be any type of the indirect conversion type and the direct conversion type, the case of the indirect conversion type is mainly described as an example in the following embodiment and the like. In other words, although detail will be described later, in the pixel section 11, after the radiations Rrad are converted into visible light by the wavelength conversion layer 112, the visible light is converted into an electric signal by the photoelectric conversion layer 111A (the photoelectric conversion element 21), and is read out as signal charges.

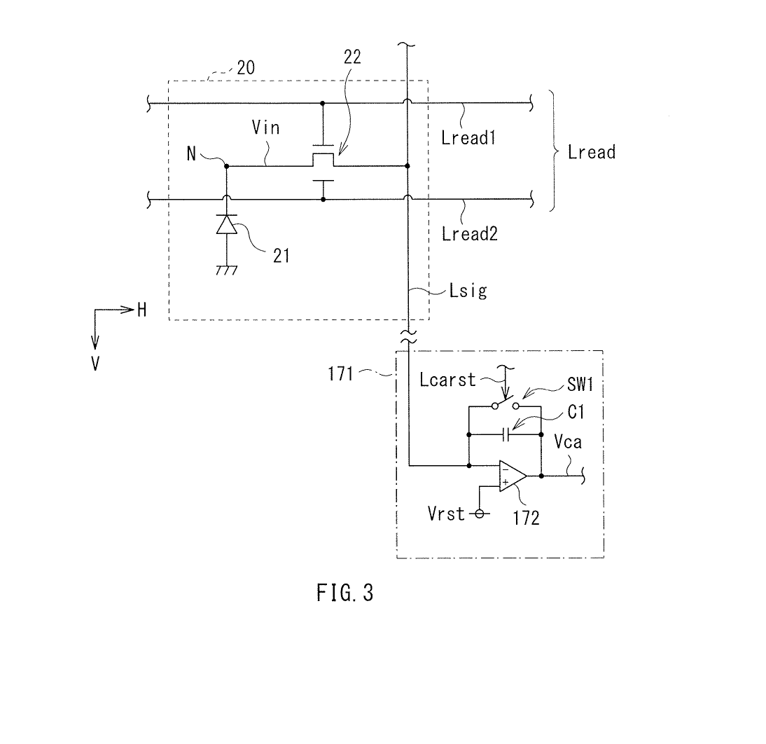

FIG. 3 exemplifies a circuit configuration (a so-called passive circuit configuration) of the pixel 20 together with a circuit configuration of a column selection section 17 described later in the A/D conversion section 14. One photoelectric conversion element 21 and one transistor 22 are provided in the passive pixel 20. In addition, a readout control line Lread (in detail, including two readout control lines Lread1 and Lread2 described later) extending along the H direction, and a signal line Lsig extending along the V direction are connected to the pixel 20.

For example, the photoelectric conversion element 21 may be configured of a positive intrinsic negative (PIN) type photodiode, or a metal-insulator-semiconductor (MIS) type sensor, and generates signal charges of an amount corresponding to an incident light amount. Incidentally, a cathode of the photoelectric conversion element 21 is connected to a storage node N in this case.

The transistor 22 is a transistor (a readout transistor) that is put into an ON state in response to a row scan signal supplied from the readout control line Lread to output the signal charges (an input voltage Vin) obtained by the photoelectric conversion element 21 to the signal line Lsig. The transistor 22 is configured of an N-channel (an N-type) field effect transistor (FET) in this case. However, the transistor 22 may be configured of a P-channel (a P-type) FET, or the like.

For example, the transistor 22 may have a so-called dual gate structure including two gates (a first gate electrode 120A and a second gate electrode 120B) that are oppositely disposed with a semiconductor layer (a semiconductor layer 126) in between. However, the device structure of the transistor 22 is not limited thereto, and may be a top-gate type or a bottom gate type (described later), for example.

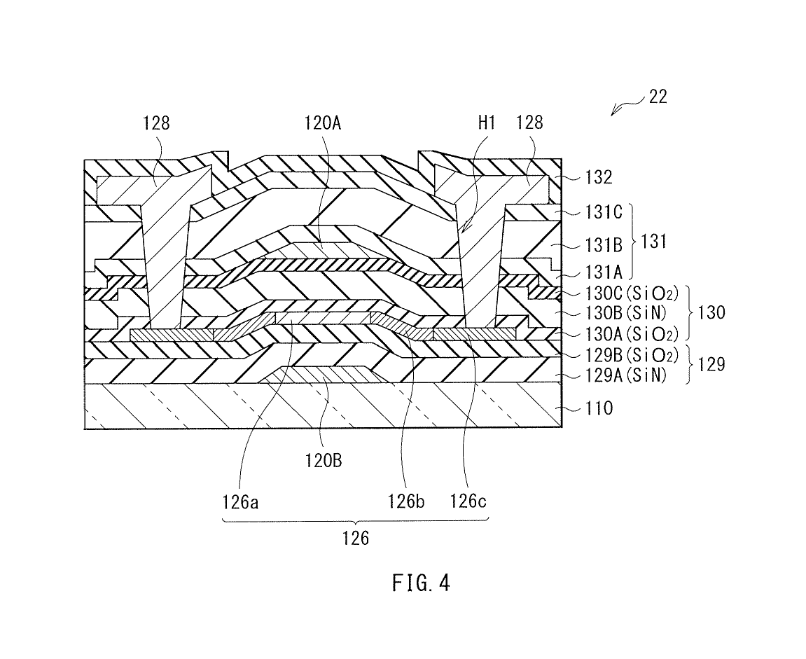

FIG. 4 illustrates a sectional-surface structure of the transistor 22. The transistor 22 may include, on a substrate 110, for example, a second gate electrode 120B (a second gate electrode) and a second gate insulating film 129 (a second gate insulating film) that is formed so as to cover the second gate electrode 120B. On the second gate insulating film 129, the semiconductor layer 126 including a channel layer (an active layer) 126a, a lightly doped drain (LDD) layer 126b, and an N+ layer 126c is provided. A first gate insulating film 130 (a first gate insulating film) is formed to cover the semiconductor layer 126, and a first gate electrode 120A (a first gate electrode is provided on the first gate insulating film. Each of the first gate electrode 120A and the second gate electrode 120B is formed to face the active layer 126a of the semiconductor layer 126. A first interlayer insulating film 131 having contact holes H1 is formed on the first gate electrode 120A, and source-drain electrodes 128 are formed so as to fill the contact holes H1. A second interlayer insulating film 132 is provided so as to cover the first interlayer insulating film 131 and the source-drain electrodes 128.

For example, the semiconductor layer 126 may be formed of a silicon-based semiconductor such as amorphous silicon, microcrystalline silicon, and polycrystalline silicon (poly-silicon), and desirably formed of low temperature poly-silicon (LTPS). Alternatively, the semiconductor layer 126 may be formed of an oxide semiconductor such as indium gallium zinc oxide (InGaZnO) and zinc oxide (ZnO). In the semiconductor layer 126, the LDD layer 126b is formed between the channel layer 126a and the N+ layer 126c in order to reduce a leakage current. The source-drain electrodes 128 function as a source or a drain, and may be single layer films each formed of, for example, titanium (Ti), aluminum (Al), molybdenum (Mo), tungsten (W), chromium (Cr), or the like, or stacked film including two or more thereof.

Each of the first gate electrode 120A and the second gate electrode 120B may be a single layer film formed of, for example, molybdenum, titanium, aluminum, tungsten, chromium, or the like or a stacked layer film including two or more thereof. The first gate electrode 120A and the second gate electrode 120B are provided to face each other with the second gate insulating film 129, the semiconductor layer 126, and the first gate insulating film 130 in between as described above.

Incidentally, the first gate electrode 120A and the second gate electrode 120B are connected to the readout control lines Lread1 and Lread2, respectively, which are illustrated in FIG. 3. For example, the readout control lines Lread1 and Lread2 may be disposed while being electrically short-circuited, and are supplied with the same voltage. Therefore, the first gate electrode 120A and the second gate electrode 120B are maintained at the same voltage. However, the first gate electrode 120A and the second gate electrode 120B may be electrically controlled separately. For example, a source (the source-drain electrode 128) of the transistor 22 may be connected to the signal line Lsig, and a drain (the source-drain electrode 128) may be connected to the cathode of the photoelectric conversion element 21 through the storage node N. Moreover, an anode of the photoelectric conversion element 21 is connected to the ground (is grounded).

### (Structure of Gate Insulating Film)

Each of the second gate insulating film 129 and the first gate insulating film 130 may include, for example, a silicon oxide film (silicon compound film containing oxygen) such as silicon oxide (SiOₓ) and silicon oxynitride (SiON). Specifically, for example, each of the second gate insulating film 129 and the first gate insulating film 130 may be a single layer film formed of silicon oxide, silicon oxynitride, or the like, or a stacked layer film including such a silicon oxide film and silicon nitride film such as silicon nitride (SiNₓ) film. The above-described silicon oxide film is provided on the semiconductor layer 126 side (adjacent to the semiconductor layer 126) in any of the second gate insulating film 129 and the first gate insulating film 130. For example, when the semiconductor layer 126 is formed of the above-described material (amorphous silicon, microcrystalline silicon, polycrystalline silicon, and oxide semiconductor), the silicon oxide film is formed adjacent to the semiconductor layer 126 for a reason in the manufacturing process.

In the present embodiment, each of the second gate insulating film 129 and the first gate insulating film 130 is a stacked layer film. Specifically, the second gate insulating film 129 may be configured by stacking, for example, a silicon nitride film 129A and a silicon oxide film 129B in order from the substrate 110 side. The first gate insulating film 130 may be configured by stacking, for example, a silicon oxide film 130A, a silicon nitride film 130B, and a silicon oxide film 130C in order from the semiconductor layer 126 side.

In the above-described structure, the silicon oxide film included in one or both of the first gate insulating film 130 and the second gate insulating film 129 (namely, one or more of the silicon oxide films 130A, 130C, and 129B) is a porous film. Desirably, the silicon oxide films 130A and 129B that are formed adjacent to the semiconductor layer 126 may be porous films. Alternatively, only one of the silicon oxide films 130A and 129B may be a porous film. In this case, the silicon oxide film 130A adjacent to the upper side of the semiconductor layer 126 may be desirably a porous film, which provides an effect equivalent to that in the case where both the silicon oxide films 130A and 129B are porous films.

Film density of the silicon oxide film 130A as the porous film may be desirably smaller than that of the silicon oxide film formed in a layer different from the first gate insulating film 130 (for example, silicon oxide films 131A and 131C formed in the first interlayer insulating film 131), and may be desirably 2.55 g/cm³ or lower. Moreover, the porous film having such film density is allowed to be formed by adjusting a film formation conditions in manufacturing process. For example, appropriate adjustment of the film formation condition (such as substrate temperature and chamber pressure) of a chemical vapor deposition (CVD) apparatus in the film formation process of the silicon oxide film 130A may make it possible to form the silicon oxide film 130A low in film density. The porous film formed in such a way is high in etching rate (etching speed) at the time of processing the silicon oxide film 130A. In other words, the wet etching rate (or a dry etching rate, hereinafter the same) at the time of processing the silicon oxide film 130A is larger (faster) than the wet etching rate of the silicon oxide films 131A and 131C. Specifically, the wet etching rate of the silicon oxide film 130A may be, for example, 1.1 times or more and 2.0 times or lower than the wet etching rate of the silicon oxide films 131A and 131C, and may be, for example, about 1.4 times.

Each of the first interlayer insulating film 131 and the second interlayer insulating film 132 may be a single layer film formed of, for example, silicon oxide, silicon oxynitride, or silicon nitride, or a stacked layer film including two or more thereof. For example, the first interlayer insulating film 131 may be configured by stacking the silicon oxide film 131A, a silicon nitride film 131B, and the silicon oxide film 131C in order from the substrate 110 side, and the second interlayer insulating film 132 may be formed of, for example, silicon oxide.

Among them, the first interlayer insulating film 131 may be desirably formed of a dense film in order to suppress a leakage current (to improve electrical insulation property). Specifically, the silicon oxide film 130A of the first gate insulating film 130 is a porous film relatively small in film density, whereas the first interlayer insulating film 131 is formed of a film relatively large in film density. Note that, for example, when the source-drain electrodes 128 are formed of a low-melting-point material such as aluminum, the second interlayer insulating film 132 is formed of a porous film because the second interlayer insulating film 132 is desirably formed at low temperature (for example, about 240° C. or lower) in CVD process.

As described above, in the present embodiment, at least the silicon oxide film 130A of the first gate insulating film 130 is a porous film. For example, the silicon oxide film 130A adjacent to the upper side of the semiconductor layer 126 may be desirably a porous film. In this case, the silicon oxide film 129B is formed of a dense film, similar to the silicon oxide films 131A and 131C of the first interlayer insulating film 131. Alternatively, both the silicon oxide film 130A and the silicon oxide film 129B that are adjacent to the semiconductor layer 126 may be porous films.

Note that the silicon oxide film 130A in the present embodiment corresponds to a specific example of “first silicon oxide film” of the present disclosure, and the silicon oxide film 129B corresponds to a specific example of “third silicon oxide film” of the present disclosure. Moreover, “second silicon oxide film” of the present disclosure is only necessary to be provided in a layer different from the first gate insulating film 130. For example, when only the silicon oxide film 130A is a porous film, the silicon oxide film 129B of the second gate insulating film 129 corresponds to a specific example of the “second silicon oxide film”. Alternatively, when both the silicon oxide film 130A and the silicon oxide film 129B are porous films, the silicon oxide films 131A and 131C of the first interlayer insulating film 131 correspond to a specific example of the “second silicon oxide film”.

### (Row Scan Section 13)

The row scan section 13 is a pixel drive section (a row scan circuit) that includes a shift resister circuit, a predetermined logical circuit, and the like that are described later, and performs driving (linear sequential scanning) of the plurality of pixels 20 in the pixel section 11 on a row basis (on a horizontal line basis). Specifically, the row scan section 13 may perform image pickup operation such as readout operation and reset operation of the pixels 20, for example, through the linear sequential scanning. Note that the linear sequential scanning is performed by supplying the row scan signal described above to the pixels 20 through the readout control line Lread. (A/D Conversion Section 14)

The A/D conversion section 14 includes a plurality of column selection sections 17 each provided for a plurality of (four, in this case) signal lines Lsig. The A/D conversion section 14 performs A/D conversion (analog to digital conversion) based on a signal voltage (a voltage corresponding to the signal charge) input through the signal lines Lsig. Output data Dout (an image pickup signal) formed of digital signals is generated accordingly, and is output to the outside.

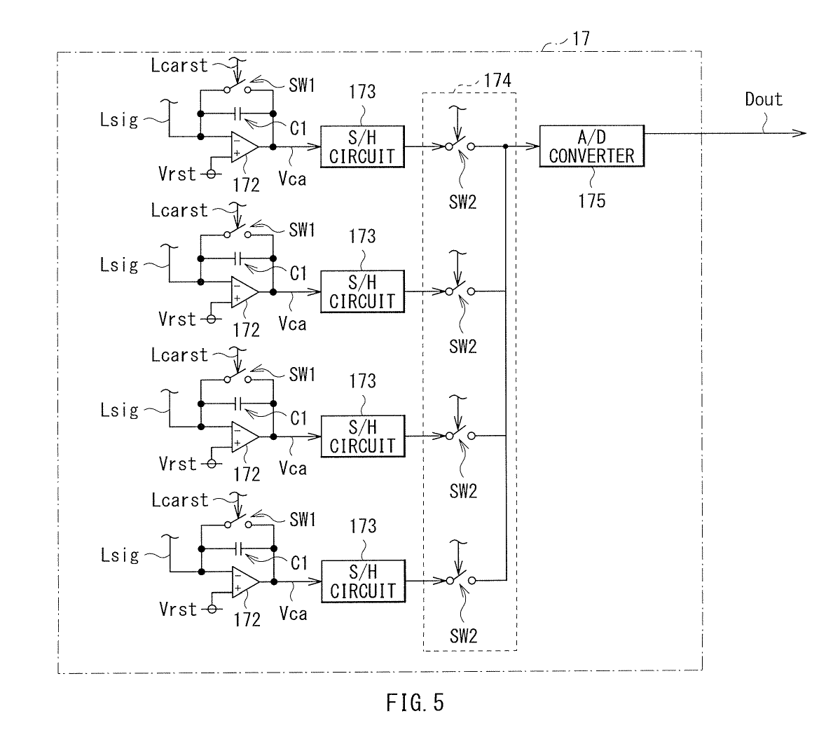

For example, as illustrated in FIG. 5, each of the column selection sections 17 includes charge amplifiers 172, capacitors (for example, feedback capacitors, or the like) C1, switches SW1, sample and hold (S/H) circuits 173, a multiplexer circuit (a selection circuit) 174 including four switches SW2, and an A/D converter 175. Among them, the charge amplifier 172, the capacitor C1, the switch SW1, the S/H circuit 173, and the switch SW2 are provided one by one for each signal line Lsig. The multiplexer circuit 174 and the A/D converter 175 are provided for each column selection section 17.

The charge amplifier 172 is an amplifier converting the signal charges read out from the signal line Lsig into a voltage (Q-V conversion). In the charge amplifier 172, an input terminal on a negative side (a minus side) is connected to an end of the signal line Lsig, and an input terminal on a positive side (a plus side) receives a predetermined reset voltage Vrst. An output terminal of the charge amplifier 172 and the input terminal on the negative side are feedback connected through a parallel connection circuit of the capacitor C1 and the switch SW1. In other words, a first terminal of the capacitor C1 is connected to the input terminal on the negative side of the charge amplifier 172, and a second terminal thereof is connected to the output terminal of the charge amplifier 172. Likewise, a first terminal of the switch SW1 is connected to the input terminal on the negative side of the charge amplifier 172, and a second terminal thereof is connected to the output terminal of the charge amplifier 172. Note that the ON-OFF state of the switch SW1 is controlled by the control signal (an amplifier reset control signal) supplied from the system control section 16 through an amplifier reset control line Lcarst.

The S/H circuit 173 is a circuit that is disposed between the charge amplifier 172 and the multiplexer circuit 174 (the switch SW2), and temporarily holds an output voltage Vca from the charge amplifier 172.

The multiplexer circuit 174 is a circuit that selectively connects or blocks between each of the S/H circuits 173 and the A/D converter 175 when one of the four switches SW2 is sequentially put into ON state in response to scan drive by the column scan section 15.

The A/D converter 175 is a circuit that performs the A/D conversion on the output voltage from the S/H circuit 173, which is input through the switch SW2, to generate and output the above-described output data Dout.

### (Column Scan Section 15)

The column scan section 15 may include, for example, a shift resistor, an address decoder, and the like, which are not illustrated, and scans and drives in order the switches SW2 in the column selection section 17 described above. The signals (the above-described output data Dout) of the respective pixels 20 read out through the respective signal lines Lsig are output to the outside in order by such selection scanning by the column scan section 15.

### (System Control Section 16)

The system control section 16 controls operation of each of the row scan section 13, the A/D conversion section 14, and the column scan section 15. Specifically, the system control section 16 has a timing generator generating the various kinds of timing signals (control signals) described above, and performs drive control of the row scan section 13, the A/D conversion section 14, and the column scan section 15, based on the various kinds of timing signals generated by the timing generator. The row scan section 13, the A/D conversion section 14, and the column scan section 15 each perform image pickup driving (linear sequential image pickup driving) to the plurality of pixels 20 in the pixel section based on the control of the system control section 16, and thus the output data Dout is acquired from the pixel section 11.

### (Function and Effects)

In the radiation image pickup unit 1 according to the present embodiment, when the radiations Rrad enter the pixel section 11, signal charges based on the incident light are generated in each pixel 20 (in this example, the photoelectric conversion element 21). At this time, more specifically, voltage change according to the node capacitance is caused by accumulation of the generated signal charges, in the storage node N illustrated in FIG. 3. Accordingly, an input voltage Vin (a voltage corresponding to the signal charges) is supplied to the drain of the transistor 22. After that, when the transistor 22 is put into ON state in response to the row scan signal supplied from the readout control line Lread (Lread1 and Lread2), the above-described signal charges are read out to the signal lines Lsig.

The signal charges read out in this way are input to the column selection section 17 in the A/D conversion section 14 for each of the plurality of (four, herein) pixel columns through the signal line Lsig. In the column selection section 17, first, the Q-V conversion (conversion from the signal charges to the signal voltage) is performed for each signal charge input from each signal line Lsig, in a charge amplifier circuit 171 configured of the charge amplifier 172 and the like. Subsequently, the A/D conversion is performed on the converted signal voltage (the output voltage Vca from the charge amplifier 172) in the A/D converter 175 through the S/H circuit 173 and the multiplexer circuit 174, to generate the output data Dout (the image pickup signal) formed of digital signals. In this way, the output data Dout is sequentially output from each column selection section 17, and is transmitted to the outside (or is input to an internal memory not illustrated).

In this case, out of the radiations Rrad that have entered the radiation image pickup unit 1, a radiation not absorbed by the above-described wavelength conversion layer 112 (or the direct conversion layer 111B) and leaking into the lower layer is present. When the transistor 22 is exposed to such a radiation, following defects may occur. Specifically, the transistor 22 includes the silicon oxide films (the silicon oxide films 129B, 130A, 130C, and the like) in the second gate insulating film 129 and the first gate insulating film 130. When the radiation enters the silicon oxide film, electrons in the film are excited by so-called photoelectric effect, Compton scattering, electron pair generation, or the like. As a result, positive holes are trapped and accumulated in the silicon oxide film, and positive holes are also trapped and accumulated at the interface with the channel layer 126a. Therefore, for example, shift of a threshold voltage Vth of the transistor 22, deterioration of the threshold value (an S value), and the like may occur, which may cause increase of the off current or decrease of the on current.

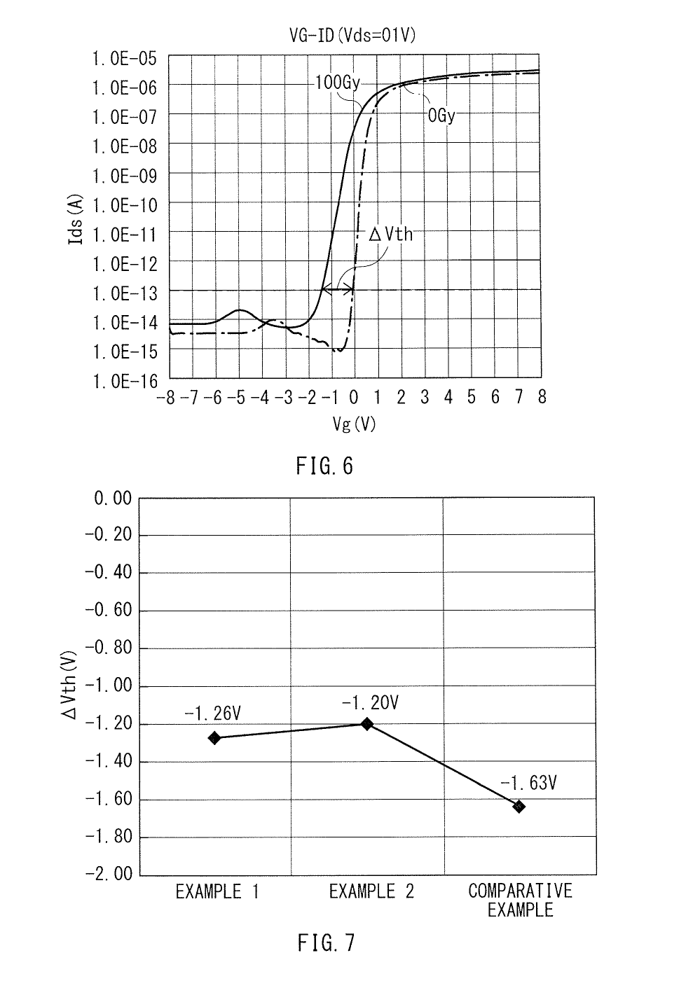

FIG. 6 illustrates relationship (current-voltage characteristics) of a drain current (a current between the source and the drain) Ids with respect to a gate voltage Vg of the transistor 22. Characteristics before radiation irradiation (an irradiation amount is 0 Gy) are illustrated by a dashed line, and characteristics after the radiation irradiation (the irradiation amount is 100 Gy) are illustrated by a solid line. Incidentally, the voltage Vds between the source and the drain is 0.1 V. In this way, after the radiation irradiation, the threshold voltage Vth (for example, the gate voltage Vg at Ids=1.0×10⁻¹³ A) is shifted to the negative side (by a shift amount of ΔVth).

In the present embodiment, the silicon oxide film 130A of the first gate insulating film 130 is the porous film as described above, which reduces influence to the semiconductor layer 126 (specifically, the active layer 126a) caused by the above-described radiation, and therefore, shift of the threshold voltage Vth hardly occurs.

FIG. 7 illustrates the shift ΔVth of the threshold voltage Vth measured in the case where both the silicon oxide film 130A and the silicon oxide film 129B were the porous films (Example 1) and in the case where only the silicon oxide film 130A was the porous film (Example 2). Moreover, as a comparative example, the shift ΔVth of the threshold voltage Vth in the case where the porous film is not formed is also illustrated. Note that the wet etching rate was defines as 1 in the comparative example, and the wet etching rate of each of the silicon oxide film 129B and the silicon oxide film 130A was set to 1.4 in the Example 1. In addition, in the Example 2, the wet etching rate of the silicon oxide film 129B was set to 1, and the wet etching rate of the silicon oxide film 130A was set to 1.4. As a result, the shift ΔVth was −1.26 V in the Example 1, was −1.20 in the Example 2, and was −1.63 V in the comparative example. Note that a symbol of “− (minus)” indicates shift on the negative side.

From these results, it is found that the shift ΔVth in the Example 1 in which both the silicon oxide films 129B and 130A were the porous films and the shift ΔVth in the Example 2 in which only the silicon oxide film was the porous film become smaller and characteristics are improved, as compared with the comparative example in which the porous film is not used. In this way, the silicon oxide film adjacent to the semiconductor layer 126 may be desirably the porous film.

Moreover, the shift amount in the Example 1 is substantially equivalent to the shift amount in the Example 2, and thus it is found that when only the silicon oxide film 130A of the silicon oxide films 129B and 130A adjacent to the semiconductor layer 126 is formed of the porous film, effects equivalent to those in the case where both the silicon oxide films 130A and 129B are formed of the porous film are obtained.

When only the silicon oxide film 130A adjacent to the upper side of the semiconductor layer 126 is the porous film, following advantages are obtained. In manufacturing process, when the second gate insulating film 129, the semiconductor layer 126, and the first gate insulating film 130 are formed, the silicon nitride film 129A, the silicon oxide film 129B, the semiconductor layer 126, the silicon oxide film 130A, the silicon nitride film 130B, and the silicon oxide film 130C are formed in order on the substrate 110 by using, for example, CVD process. At this time, formation of the silicon nitride film 129A, the silicon oxide film 129B, and the semiconductor layer 126 is continuously performed in a vacuum chamber, and then the substrate 110 is taken out of the chamber (is exposed to the air) for the reason in the manufacturing process. For example, when a low-temperature polycrystalline silicon is used as the semiconductor layer 126, the substrate 110 is taken out of the chamber once in order to perform excimer laser anneal (ELA) process. As a result, a state of the interface between the semiconductor layer 126 and the silicon oxide film 130A is easily deteriorated (contamination, roughness, and the like easily occur) while a state of the interface between the silicon oxide film 129B and the semiconductor layer 126 is retained in good condition (contamination, roughness, and the like hardly occur).

Accordingly, the semiconductor layer 126 is easily affected by the positive holes from the silicon oxide film 130A side. Therefore, the silicon oxide film 130A adjacent to the upper side of the semiconductor layer 126 is formed of the porous film, which makes it possible to effectively reduce such influence by the positive holes.

Moreover, in the dual gate type transistor 22, when the first gate electrode 120A and the second gate electrode 120B are short-circuited (maintained at the same potential) and driven, the characteristics by the device structure higher in position than the semiconductor layer 126 are dominant. Therefore, selectively forming the silicon oxide film 130A as the porous film is advantageous in characteristic improvement.

Further, the second gate insulating film 129 lower in position than the semiconductor layer 126 may be desirably formed to have film quality as dense as possible in terms of prevention of contaminant (infiltration of impurity and the like) from the substrate 110 side. In the above-described viewpoints, desirably, only the silicon oxide film 130A may be selectively formed of the porous film.

As described above, in the present embodiment, in the transistor 22 to read out the signal charges based on the radiations from each pixel 20, the first gate insulating film 130 provided between the semiconductor layer 126 and the first gate electrode 120A includes the silicon oxide film 130A, and the silicon oxide film 130A is the porous film whose film density is smaller than that of the silicon oxide film (for example, the silicon oxide films 131A and 131C) provided in a layer different from the first gate insulating film 130. As a result, it is possible to suppress shift of the threshold voltage of the transistor 22 by influence of the radiations Rrad. Accordingly, characteristics deterioration of the transistor is allowed to be suppressed to achieve high reliability.

Subsequently, modifications of the above-described embodiment will be described. Note that like numerals are used to designate substantially like components of the above-described embodiment, and the description thereof is appropriately omitted.

### <Modification 1>

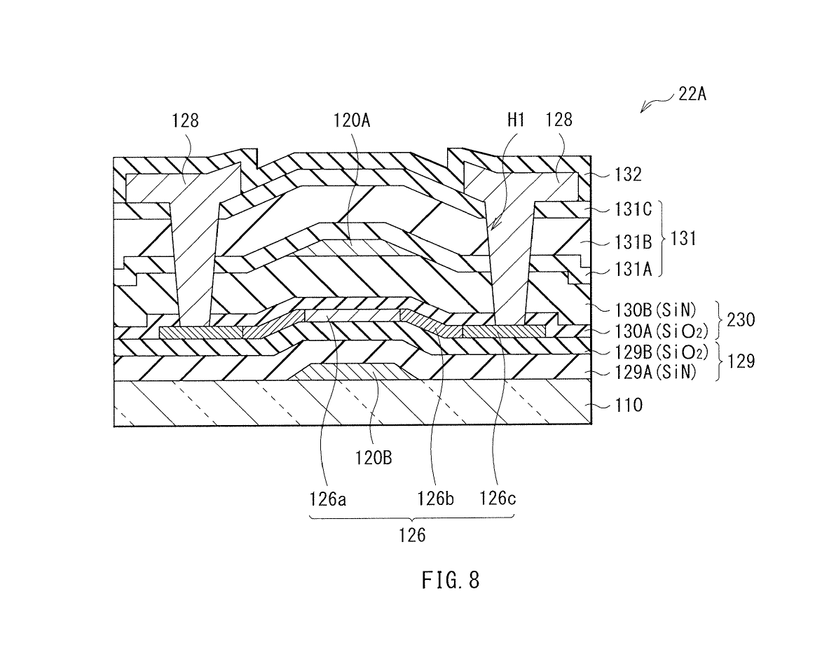

FIG. 8 illustrates a sectional-surface structure of a transistor (a transistor 22A) according to a modification 1. In the above-described embodiment, the first gate insulating film (the first gate insulating film 130 is formed as a three-layer stacked film including the silicon oxide film 130A, the silicon nitride film 130B, and the silicon oxide film 130C; however, the stacked structure of the first gate insulating film is not limited thereto. For example, as a first gate insulating film (a first gate insulating film 230) of the transistor 22A in the present modification, the first gate insulating film may have a two-layer structure in which the silicon oxide film 130A and the silicon nitride film 130B are stacked in order from the semiconductor 126 side. In such a structure, effects equivalent to those in the above-described embodiment are obtainable as long as the silicon oxide film 130A included in the first gate insulating film 230 is the porous film.

### <Modification 2>

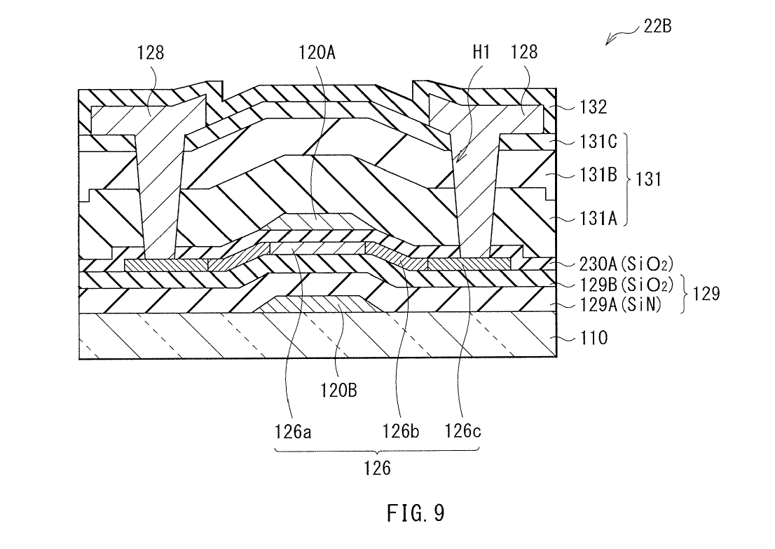

FIG. 9 illustrates a sectional-surface structure of a transistor (a transistor 22B) according to a modification 2. In the above-described embodiment, the first gate insulating film (the first gate insulating film 130) is formed as the three-layer stacked film; however, the first gate insulating film (a first gate insulating film 230A) may be formed of a single layer film of a silicon oxide film as in the present modification. In this way, even when the first gate insulating film 230A is formed as a single layer structure of a silicon oxide film, effects equivalent to those in the above-described embodiment are obtainable as long as the first gate insulating film 230A is the porous film.

### <Modification 3>

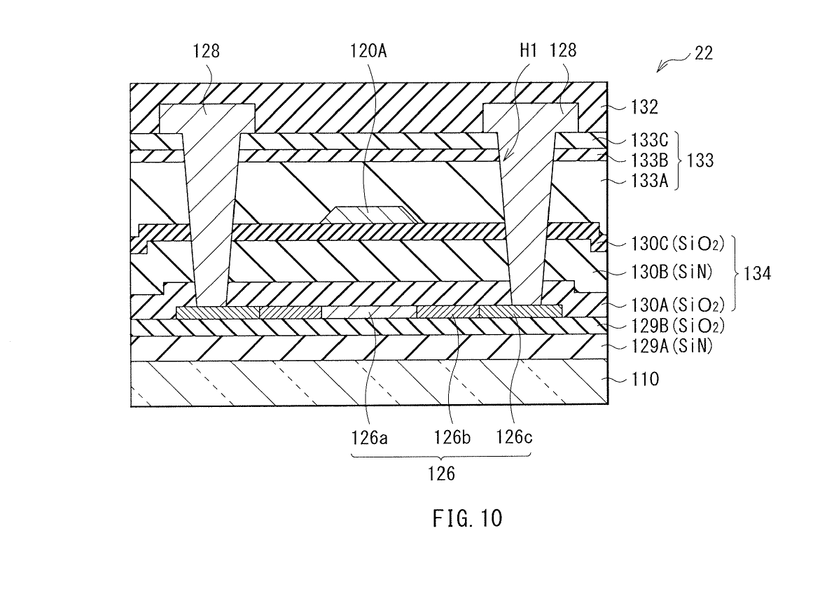

FIG. 10 illustrates a sectional-surface structure of a transistor according to a modification 3. Although the dual gate type device structure has been exemplified in the above-described embodiment, the transistor of the present disclosure may be a top gate type device structure as in the present modification. The device structure in the present modification may include, for example, the silicon nitride film 129A, the silicon oxide film 129B, the semiconductor layer 126, a first gate insulating film 134 (a first gate insulating film), and the first gate electrode 120A in order from the substrate 110 side. The first gate insulating film 134 may have a stacked-layer structure similar to that of the second gate insulating film 130 in the above-described embodiment, for example. Moreover, a first interlayer insulating film 133 is formed on the first gate insulating film 134 and the first gate electrode 120A, and contact holes H1 penetrating through the first interlayer insulating film 133 and the first gate insulating film 134 are formed. The source-drain electrodes 128 are provided on the first interlayer insulating film 133 so as to fill the contact holes H1. The first interlayer insulating film 133 may be a stacked-layer film including, for example, a silicon oxide film 133A, a silicon nitride film 133B, and a silicon oxide film 133C in order from the first gate electrode 120A side. The second interlayer insulating film 132 is formed so as to cover the first interlayer insulating film 133 and the source-drain electrodes 128.

Also in the present modification, the silicon oxide films 130A and 130C (desirably, the silicon oxide film 130A adjacent to the semiconductor layer 126) of the first gate insulating film 134 are the porous films as described above, which makes it possible to obtain effects equivalent to those in the above-described embodiment.

Note that, also in the present modification, the stacked-layer structure of the first gate insulating film 134 is not limited to that described above, and may be two-layer structure or a single layer film of a silicon oxide as long as the first gate insulating film 134 includes a silicon oxide film.

### <Modification 4>

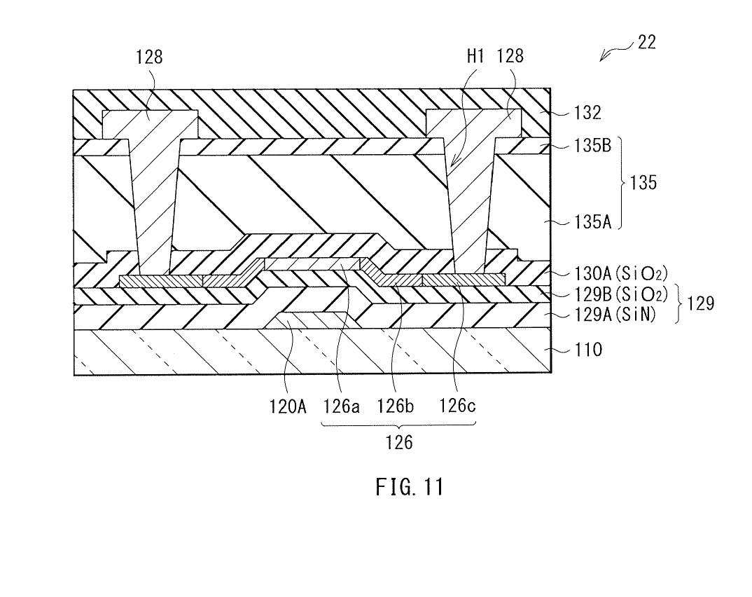

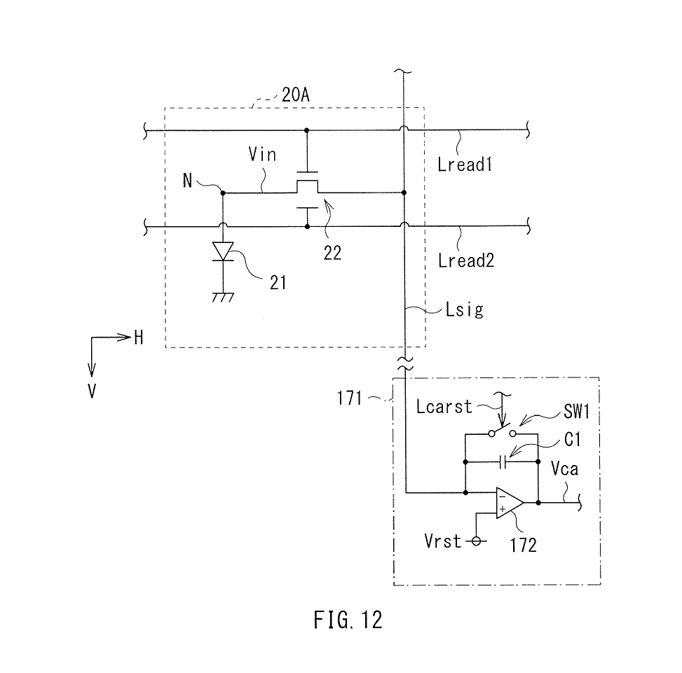

FIG. 11 illustrates a sectional-surface structure of a transistor according to a modification 4. Although the dual gate type device structure has been exemplified in the above-described embodiment, the transistor of the present embodiment may have a bottom gate type device structure as in the present modification. The device structure of the present modification may include, for example, the first gate electrode 120, the first gate insulating film 129, the semiconductor layer 126, and the silicon oxide film 130A in order from the substrate 110 side. Moreover, the first interlayer insulating film 135 is formed on the silicon oxide film 130A, and contact holes H1 penetrating through the first interlayer insulating film 135 and the silicon oxide film 130A are formed. The source-drain electrodes 128 are provided on the first interlayer insulating film 135 so as to fill the contact holes H1. The first interlayer insulating film 135 may be a stacked-layer film including, for example, a silicon nitride film 135A and a silicon oxide film 135B in order from the silicon oxide film 130A.

Also in the present modification, the silicon oxide film 129B of the first gate insulating film 129 is the porous film as described above, which makes it possible to obtain effects equivalent to those in the above-described embodiment.

### <Modification 5>

FIG. 12 illustrates a circuit configuration of a pixel (a pixel 20A) according to a modification 5, together with a circuit configuration example of the charge amplifier circuit 171 described in the above-described embodiment. The pixel 20A in the present modification has a so-called passive circuit configuration as with the pixel 20 in the embodiment, and includes one photoelectric conversion element 21 and one transistor 22. In addition, the readout control line Lread (Lread1 and Lread2) extending along the H direction and the signal line Lsig extending along the V direction are connected to the pixel 20A.

Incidentally, in the pixel 20A of the present modification, unlike the pixel 20 of the above-described embodiment, the anode of the photoelectric conversion element 21 is connected to the storage node N, and the cathode thereof is connected to the ground (is grounded). In this way, in the pixel 20A, the anode of the photoelectric conversion element 21 may be connected to the storage node N, and even in the case where this configuration is employed, effects similar to those of the radiation image pickup unit 1 according to the above-described embodiment are obtainable.

### <Modification 6>

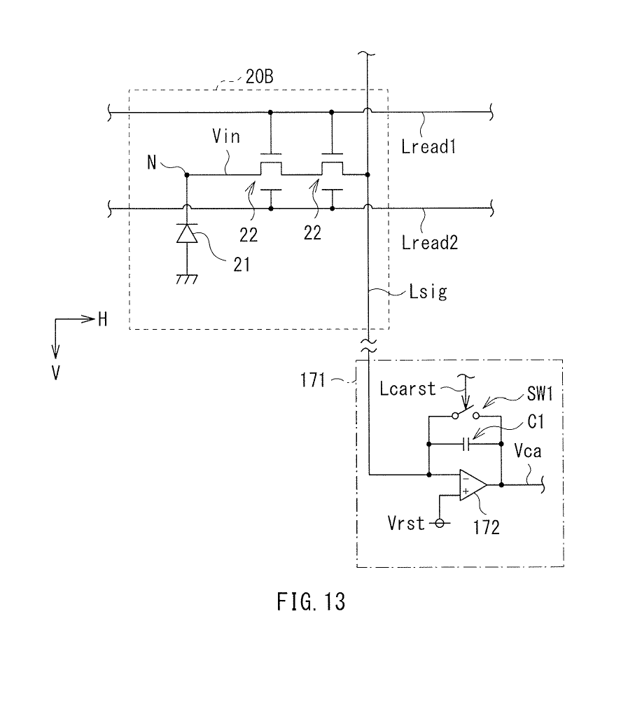

FIG. 13 illustrates a circuit configuration of a pixel (a pixel 20B) according to a modification 6, together with the circuit configuration example of the charge amplifier circuit 171 described in the above-described embodiment. The pixel 20B in the present modification has a so-called passive circuit configuration as with the pixel 20 in the embodiment, and includes one photo electric conversion element 21. The pixel 20B is connected to the readout control lines Lread1 and Lread2 that extend along the H direction and is connected to the signal line Lsig extending along the V direction.

However, in the present modification, the pixel 20B includes two transistors 22. The two transistors 22 are connected in series to each other (a source or a drain of one of the transistors 22 is electrically connected to a source or a drain of the other transistor 22). In addition, a first gate of each of the transistors 22 is connected to the readout control line Lread1, and a second gate of each of the transistors 22 is connected to the readout control line Lread2. In this way, two transistors 22 are provided in one pixel 20B, which makes it possible to reduce off-leak.

As described above, two transistors 22 connected in series to each other may be provided in the pixel 20B, and also in this case, effects equivalent to those in the above-described embodiment are obtainable. Note that three or more transistors may be connected in series to one another.

### <Modifications 7-1 and 7-2>

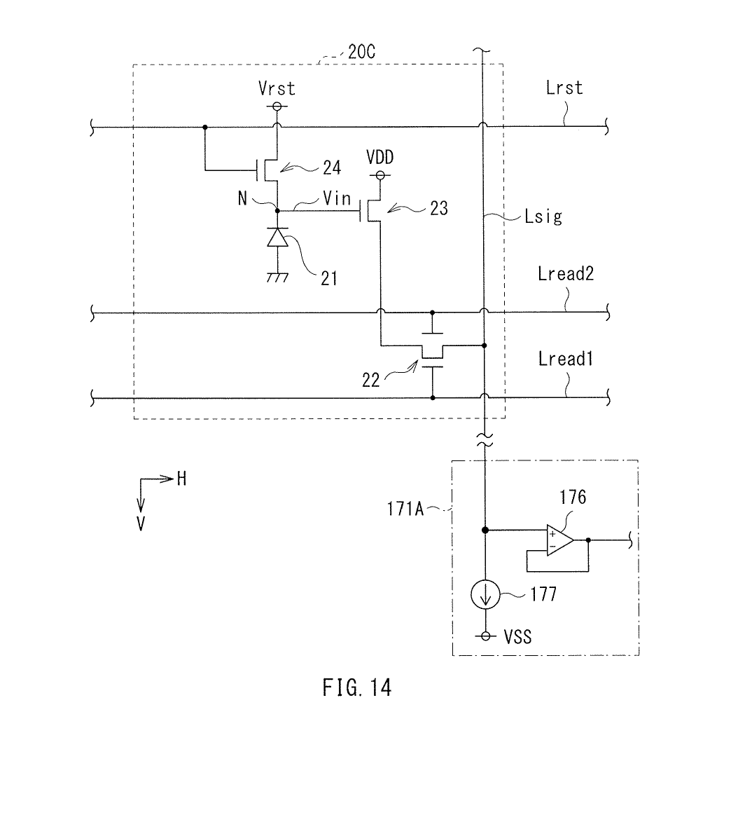

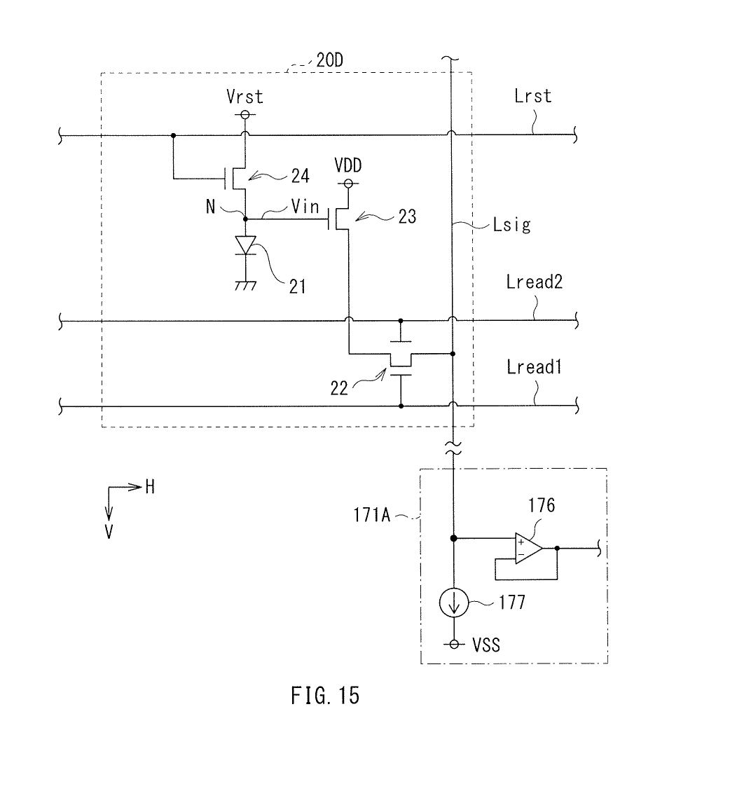

FIG. 14 illustrates a circuit configuration of a pixel (a pixel 20C) according to a modification 7-1, together with a circuit configuration example of a charge amplifier circuit 171A described below. Moreover, FIG. 15 illustrates a circuit configuration of a pixel (a pixel 20D) according to a modification 7-2, together with the circuit configuration example of the charge amplifier circuit 171A. Unlike the pixels 20, 20A, and 20B described above, the pixels 20C and 20D according to the modifications 7-1 and 7-2 each have a so-called active pixel circuit.

In each of the active pixels 20C and 20D, one photoelectric conversion element 21 and three transistors 22, 23, and 24 are provided. In addition, the readout control line Lread (Lread1 and Lread2) and the reset control line Lrst each extending along the H direction and the signal line Lsig extending along the V direction are connected to each of the pixels 20C and 20D.

In each of the pixels 20C and 20D, the gate of the transistor 22 is connected to the readout control line Lread, the source thereof is connected to the signal line Lsig, and the drain thereof is connected to a drain of the transistor 23 configuring a source follower circuit. A source of the transistor 23 is connected to a power source VDD, and a gate thereof is connected to the cathode (in the example in FIG. 14) or the anode (in the example in FIG. 15) of the photoelectric conversion element 21 and a drain of the transistor 24 that functions as a reset transistor, through the storage node N. A gate of the transistor 24 is connected to the reset control line Lrst, a source thereof is supplied with a reset voltage Vrst. In the modification 7-1, the anode of the photoelectric conversion element 21 is connected to the ground, and in the modification 7-2, the cathode of the photoelectric conversion element 21 is connected to the ground.

Moreover, in the modifications 7-1 and 7-2, the charge amplifier circuit 171A has an amplifier 176 and a constant current source 177 in place of the charge amplifier 172, the capacitor C1, and the switch SW1 in the above-described charge amplifier circuit 171. In the amplifier 176, an input terminal on a positive side is connected to the signal line Lsig, and an input terminal on a negative side and an output terminal are connected to each other to form a voltage follower circuit. Note that a first terminal of the constant current source 177 is connected to one end of the signal line Lsig, and a second terminal of the constant current source 177 is connected to a power source VSS.

### APPLICATION EXAMPLE

Subsequently, the radiation image pickup unit according to any of the above-described embodiment and modifications is applicable to a radiation image pickup display system described below.

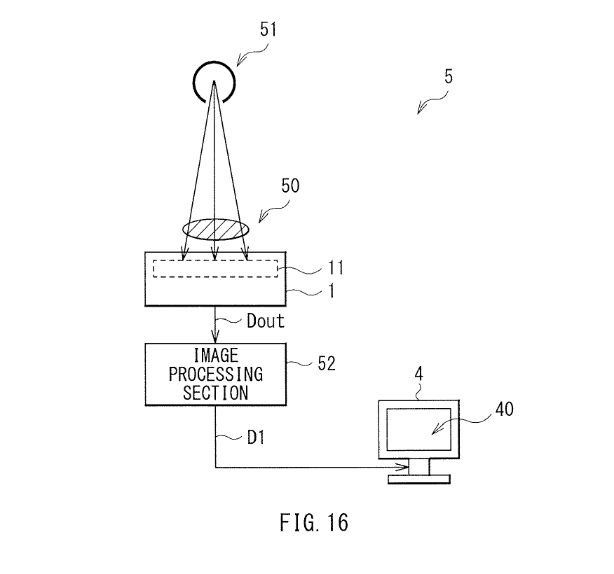

FIG. 16 schematically illustrates a schematic configuration example of a radiation image pickup display system (a radiation image pickup display system 5) according to an application example. The radiation image pickup display system 5 includes the radiation image pickup unit 1 having the pixel section 11 and the like according to the above-described embodiment and the like, an image processing section 52, and a display unit 4.

The image processing section 52 performs predetermined image processing on the output data Dout (an image pickup signal) output from the radiation image pickup unit 1 to generate image data D1. The display unit 4 performs image display based on the image data D1 that is generated by the image processing section 52, on a predetermined monitor screen 40.

In the radiation image pickup display system 5, the radiation image pickup unit 1 acquires the image data Dout of an object 50 based on radiations applied from a radiation source (a radiation source such as an X-ray source in this case) 51 to the object 50, and then outputs the image data Dout to the image processing section 52. The image processing section 52 performs the above-described predetermined image processing on the input image data Dout, and then outputs the image-processed image data (display data) D1 to the display unit 4. The display unit 4 displays image information (picked up image) on the monitor screen 40, based on the input image data D1.

As described above, in the radiation image pickup display system 5 of the present application example, the radiation image pickup unit 1 is capable of acquiring the image of the object 50 as an electric signal. Therefore, the acquired electric signal is transmitted to the display unit 4 to perform the image display. In other words, the image of the object 50 is allowed to be observed without using radiation photograph films, and moving picture shooting and moving picture display are allowed to be achieved.

Note that the above-described radiation image pickup unit 1 and the above-described radiation image pickup display system 5 are used as various kinds of image pickup units and image pickup display systems that obtain an electric signal based on the radiation Rrad. For example, such a radiation image pickup unit and such a radiation image pickup display system are applicable to medical X-ray image pickup units (such as digital radiography), X-ray inspection apparatuses for personal effects used at air ports and the like, industrial X-ray image pickup units (for example, apparatuses for examination of dangerous goods in a container), and the like.

Hereinbefore, although the embodiment, the modifications, and the application example have been described, the contents of the present disclosure are not limited to the embodiment and the like, and various modifications may be made. For example, the film configured by stacking one to three insulating films has been exemplified as the first gate insulating film and the second gate insulating film in the above-described embodiment and the like. However, each of the first and second gate insulating films may be configured by stacking four or more insulating films. The effects of the present disclosure are allowed to be obtained as long as a silicon oxide film is provided on the semiconductor layer side of the first gate insulating film and the silicon oxide film is a porous film even in any of the stacked-layer structures.

Moreover, the circuit configuration of the pixel in the pixel section according to the above-described embodiment and the like is not limited to those described in the above-described embodiments and the like (the circuit configurations of the pixels 20, and 20A to 20D), and may be other circuit configurations. Likewise, the circuit configurations of the row scan section, the column selection section, and the like are not limited to those described in the above-described embodiment and the like, and may be other circuit configurations.

Further, the pixel section, the row scan section, the A/D conversion section (the column selection section), the column scan section, and the like that are described in the above-described embodiment and the like may be formed on the same substrate, for example. Specifically, for example, a polycrystalline semiconductor formed of low-temperature polycrystalline silicone or the like may be used, which makes it possible to form the switches and the like in the circuit part on the same substrate. Accordingly, it is possible to perform drive operation on the same substrate, for example, based on control signals from an external system control section, and thus it is possible to achieve improvement in reliability at the time of decreasing width of a bezel (a frame structure of three free sides) and wiring connection.

Note that the present disclosure may be configured as follows.

(1) A radiation image pickup unit including:

a plurality of pixels each configured to generate a signal charge based on a radiation; and

a field effect transistor to readout the signal charges from the plurality of pixels, wherein

the transistor includes

a semiconductor layer including an active layer,

a first gate electrode disposed to face the semiconductor layer,

a first gate insulating film provided between the semiconductor layer and the first gate electrode, and including a first silicon oxide film,

a source electrode and a drain electrode that are electrically connected to the semiconductor layer, and

a second silicon oxide film provided in a layer different from the first gate insulating film, and

the first silicon oxide film of the first gate insulating film is a porous film lower in film density than the second silicon oxide film.

(2) The radiation image pickup unit according to (1), wherein the transistor further includes

a second gate electrode disposed to face the first gate electrode with the semiconductor layer in between, and

a second gate insulating film provided between the semiconductor layer and the second gate electrode, and including a third silicon oxide film.

(3) The radiation image pickup unit according to (2), wherein

the transistor includes the second gate insulating film, the semiconductor layer, the first gate insulating film, and the first gate electrode in this order on the second gate electrode, and

the third silicon oxide film corresponds to the second silicon oxide film.

(4) The radiation image pickup unit according to (2), wherein

the transistor includes the second gate insulating film, the semiconductor layer, the first gate insulating film, and the first gate electrode in this order on the second gate electrode,

a first interlayer insulating film including the second silicon oxide film is provided on the first gate electrode of the transistor, and

both the first silicon oxide film and the third silicon oxide film are the porous films.

(5) The radiation image pickup unit according to any one of (1) to (4), wherein the film density of the porous film is equal to or lower than 2.55 g/cm³.

(6) The radiation image pickup unit according to any one of (1) to (5), wherein the first silicon oxide film is formed adjacent to the semiconductor layer.

(7) The radiation image pickup unit according to any one of (1) to (6), wherein

the transistor includes the second gate insulating film, the semiconductor layer, the first gate insulating film, and the first gate electrode in this order on the second gate electrode,

the transistor further includes a first interlayer insulating film and a second interlayer insulating film, the first interlayer insulating film being provided on the first gate electrode of the transistor and including the second silicon oxide film, the second interlayer insulating film being provided to cover the first interlayer insulating film, the source electrode, and the drain electrode, and

the second interlayer insulating film is the porous film.

(8) The radiation image pickup unit according to (1), wherein the transistor includes the first gate insulating film and the first gate electrode in this order on the semiconductor layer.

(9) The radiation image pickup unit according to (1), wherein the transistor includes the first gate insulating film and the semiconductor layer in this order on the first gate electrode.

(10) The radiation image pickup unit according to any one of (1) to (9), wherein the semiconductor layer includes one of polycrystalline silicon, microcrystalline silicon, amorphous silicon, and oxide semiconductor.

(11) The radiation image pickup unit according to (10), wherein the semiconductor layer includes low-temperature polycrystalline silicon.

(12) The radiation image pickup unit according to any one of (1) to (11), wherein

each of the plurality of pixels includes a photoelectric conversion element, and

a wavelength conversion layer is provided on a light incident side of the plurality of pixels, the wavelength conversion layer being configured to convert a wavelength of the radiation into a wavelength in a sensitive range of the photoelectric conversion element.

(13) The radiation image pickup unit according to (12), wherein the photoelectric conversion element is configured of one of a PIN photodiode and an MIS sensor.

(14) The radiation image pickup unit according to any one of (1) to (11), wherein each of the plurality of pixels is configured to absorb the radiation to generate the signal charge.

(15) The radiation image pickup unit according to any one of (1) to (14), wherein the radiation is an X-ray.

(16) A radiation image pickup display system provided with a radiation image pickup unit and a display unit configured to perform image display based on an image pickup signal that is obtained by the radiation image pickup unit, the radiation image pickup unit including:

a plurality of pixels each configured to generate a signal charge based on a radiation; and

a field effect transistor to readout the signal charges from the plurality of pixels, wherein

the transistor includes

a semiconductor layer including an active layer,

a first gate electrode disposed to face the semiconductor layer,

a first gate insulating film provided between the semiconductor layer and the first gate electrode, and including a first silicon oxide film,

a source electrode and a drain electrode that are electrically connected to the semiconductor layer, and

a second silicon oxide film provided in a layer different from the first gate insulating film, and

the first silicon oxide film of the first gate insulating film is a porous film lower in film density than the second silicon oxide film.

It should be understood by those skilled in the art that various modifications, combinations, sub-combinations, and alterations may occur depending on design requirements and other factors insofar as they are within the scope of the appended claims or the equivalents thereof.

What is claimed is:

1. A radiation image pickup unit comprising:
a plurality of pixels each configured to generate a signal charge based on a radiation; and
a field effect transistor to readout the signal charges from the plurality of pixels, wherein
the transistor includes
a semiconductor layer including an active layer,
a first gate electrode disposed to face the semiconductor layer,
a first gate insulating film provided between the semiconductor layer and the first gate electrode, and including a first silicon oxide film,
a source electrode and a drain electrode that are electrically connected to the semiconductor layer, and
a second silicon oxide film provided in a layer different from the first gate insulating film, and
the first silicon oxide film of the first gate insulating film is a porous film lower in film density than the second silicon oxide film.

2. The radiation image pickup unit according to claim 1, wherein the transistor further includes
a second gate electrode disposed to face the first gate electrode with the semiconductor layer in between, and
a second gate insulating film provided between the semiconductor layer and the second gate electrode, and including a third silicon oxide film.

3. The radiation image pickup unit according to claim 2, wherein
the transistor includes the second gate insulating film, the semiconductor layer, the first gate insulating film, and the first gate electrode in this order on the second gate electrode, and
the third silicon oxide film corresponds to the second silicon oxide film.

4. The radiation image pickup unit according to claim 2, wherein
the transistor includes the second gate insulating film, the semiconductor layer, the first gate insulating film, and the first gate electrode in this order on the second gate electrode,
a first interlayer insulating film including the second silicon oxide film is provided on the first gate electrode of the transistor, and
both the first silicon oxide film and the third silicon oxide film are the porous films.

5. The radiation image pickup unit according to claim 1, wherein the film density of the porous film is equal to or lower than 2.55 g/cm³.

6. The radiation image pickup unit according to claim 1, wherein the first silicon oxide film is formed adjacent to the semiconductor layer.

7. The radiation image pickup unit according to claim 1, wherein
the transistor includes the second gate insulating film, the semiconductor layer, the first gate insulating film, and the first gate electrode in this order on the second gate electrode,
the transistor further includes a first interlayer insulating film and a second interlayer insulating film, the first interlayer insulating film being provided on the first gate electrode of the transistor and including the second silicon oxide film, the second interlayer insulating film being provided to cover the first interlayer insulating film, the source electrode, and the drain electrode, and
the second interlayer insulating film is the porous film.

8. The radiation image pickup unit according to claim 1, wherein the transistor includes the first gate insulating film and the first gate electrode in this order on the semiconductor layer.

9. The radiation image pickup unit according to claim 1, wherein the transistor includes the first gate insulating film and the semiconductor layer in this order on the first gate electrode.

10. The radiation image pickup unit according to claim 1, wherein the semiconductor layer includes one of polycrystalline silicon, microcrystalline silicon, amorphous silicon, and oxide semiconductor.

11. The radiation image pickup unit according to claim 10, wherein the semiconductor layer includes low-temperature polycrystalline silicon.

12. The radiation image pickup unit according to claim 1, wherein
each of the plurality of pixels includes a photoelectric conversion element, and
a wavelength conversion layer is provided on a light incident side of the plurality of pixels, the wavelength conversion layer being configured to convert a wavelength of the radiation into a wavelength in a sensitive range of the photoelectric conversion element.

13. The radiation image pickup unit according to claim 12, wherein the photoelectric conversion element is configured of one of a PIN photodiode and an MIS sensor.

14. The radiation image pickup unit according to claim 1, wherein each of the plurality of pixels is configured to absorb the radiation to generate the signal charge.

15. The radiation image pickup unit according to claim 1, wherein the radiation is an X-ray.

16. A radiation image pickup display system provided with a radiation image pickup unit and a display unit configured to perform image display based on an image pickup signal that is obtained by the radiation image pickup unit, the radiation image pickup unit comprising:
a plurality of pixels each configured to generate a signal charge based on a radiation; and
a field effect transistor to readout the signal charges from the plurality of pixels, wherein
the transistor includes
a semiconductor layer including an active layer,
a first gate electrode disposed to face the semiconductor layer,
a first gate insulating film provided between the semiconductor layer and the first gate electrode, and including a first silicon oxide film,
a source electrode and a drain electrode that are electrically connected to the semiconductor layer, and
a second silicon oxide film provided in a layer different from the first gate insulating film, and
the first silicon oxide film of the first gate insulating film is a porous film lower in film density than the second silicon oxide film.
